(19) United States
(12) Patent Application Publication
(10) Pub. No.: US 2025/0006619 A1
(43) Pub. Date: Jan. 2, 2025

(54) PACKAGE SUBSTRATE AND SEMICONDUCTOR PACKAGE INCLUDING THE SAME

(71) Applicant: Samsung Electronics Co., Ltd., Suwon-si (KR)

(72) Inventors: Chonghee LEE, Suwon-si (KR); Yunrae CHO, Suwon-si (KR)

(73) Assignee: Samsung Electronics Co., Ltd., Suwon-si (KR)

(21) Appl. No.: 18/756,426

(22) Filed: Jun. 27, 2024

(30) Foreign Application Priority Data
Jun. 29, 2023 (KR) 10-2023-0084507

(51) Int. Cl. H01L 23/498; H01L 23/00; H01L 23/31; H01L 23/48; H01L 25/065

(52) U.S. Cl. CPC H01L 23/49838; H01L 23/49822; H01L 24/16; H01L 24/17; H01L 25/0657; H01L 23/3107; H01L 23/481; H01L 23/49816; H01L 2224/16146; H01L 2224/16227; H01L 2224/1703; H01L 2224/17055; H01L 2224/17181

(57) ABSTRACT

A package substrate includes a substrate base, a plurality of wiring pads, and a plurality of wiring lines. The substrate base includes a first surface and a second surface that is opposite to the first surface. The substrate base is divided into a plurality of regions. The plurality of wiring pads are arranged on the first surface of the substrate base and are apart from each other in a horizontal direction. The plurality of wiring lines are arranged on the first surface of the substrate base and extend from corresponding ones of the plurality of wiring pads, respectively. The plurality of wiring pads have different horizontal area in different regions of the substrate base.

### CROSS-REFERENCE TO RELATED APPLICATION

This application is based on and claims priority under 35 U.S.C. § 119 to Korean Patent Application No. 10-2023-0084507, filed on Jun. 29, 2023, in the Korean Intellectual Property Office, the disclosure of which is incorporated by reference herein in its entirety.

### BACKGROUND

The inventive concepts relate to package substrates and/or a semiconductor packages including the package substrate, and more particularly, to package substrates for forming a mold layer through a molded underfill (MUF) process and/or semiconductor packages including the package substrate.

Along with the development of the electronics industry, demand for high-functionality, high-speed, and small electronic components has increased. Thus, semiconductor chips used in such electronic components are increasingly required to have small sizes and multiple functions. In addition, the size of semiconductor packages has decreased based on small semiconductor chips. In addition, due to the demand for high-performance and low-form-factor semiconductor packages, the structure of semiconductor packages changes to a multi-chip integrated structure. Here, multi-chip integration may refer to integrating chips manufactured in different processes together into a single semiconductor package.

### SUMMARY

Some example embodiments of the inventive concepts provide package substrates configured to suppress an open circuit and a short circuit between semiconductor chips and bump pads, and/or semiconductor packages including the package substrate.

Some example embodiments of the inventive concepts provide package substrates configured to suppress the formation of voids in a mold layer during a molded underfill (MUF) process, and/or semiconductor packages including the package substrate.

The inventive concepts are not limited to those mentioned above, and the inventive concepts will be apparently understood by those skilled in the art through the following description.

According to an aspect of the inventive concepts, a package substrate may include a substrate base comprising a first surface and a second surface that is opposite to the first surface, the substrate base being divided into a plurality of regions, a plurality of wiring pads arranged on the first surface of the substrate base and apart from each other in a horizontal direction; and a plurality of wiring lines arranged on the first surface of the substrate base and extending from corresponding ones of the plurality of wiring pads, respectively, wherein the plurality of wiring pads have different horizontal areas in different regions of the substrate base.

According to an aspect of the inventive concepts, a semiconductor package may include a substrate base comprising a first surface and a second surface that is opposite to the first surface, the substrate base being divided into a plurality of regions, a plurality of wiring pads arranged on the first surface of the substrate base and apart from each other in a horizontal direction, a plurality of wiring lines extending from corresponding ones of the plurality of wiring pads, respectively, a plurality of semiconductor chips stacked on the first surface of the substrate base and each comprising a plurality of lower-surface chip pads, and a plurality of chip connection terminals arranged between the substrate base and a lowermost semiconductor chip among the plurality of semiconductor chips and between the plurality of semiconductor chips, wherein the plurality of wiring pads have different horizontal areas in different regions of the substrate base.

According to an aspect of the inventive concepts, a semiconductor package may include a substrate base comprising a first surface and a second surface that is opposite to the first surface, the substrate base being divided into a plurality of regions, a plurality of wiring pads arranged on the first surface of the substrate base and apart from each other in a horizontal direction, a plurality of wiring lines extending from corresponding ones of the plurality of wiring pads, respectively, a plurality of semiconductor chips stacked on the first surface of the substrate base and each comprising a plurality of lower-surface chip pads, external contact pads arranged on the second surface of the substrate base, an upper solder resist layer positioned in a region of the first surface of the substrate base that does not overlap the plurality of semiconductor chips, a lower solder resist layer covering the second surface of the substrate base and surrounding the external contact pads, a plurality of chip connection terminals arranged between the substrate base and a lowermost semiconductor chip among the plurality of semiconductor chips and between the plurality of semiconductor chips, and a molding layer covering the first surface of the substrate base and surrounding the plurality of semiconductor chips and the plurality of chip connection terminals, wherein the lowermost semiconductor chip comprises upper lower-surface chip pads overlapping lower wiring pads of the plurality of wiring pads, respectively, in a vertical direction, horizontal areas of the upper lower-surface chip pads are less than horizontal areas of the lower wiring pads, the plurality of wiring pads arranged in different regions of the substrate base have different horizontal areas, and the plurality of semiconductor chips have bent shapes that are convex in an identical direction.

### BRIEF DESCRIPTION OF THE DRAWINGS

Example embodiments will be more clearly understood from the following detailed description taken in conjunction with the accompanying drawings in which:

FIG. 1 is a schematic layout illustrating a package substrate according to an example embodiment;

FIG. 2 is an enlarged plan view illustrating a portion of the package substrate shown in FIG. 1;

FIG. 3 is a cross-sectional view of the package substrate, taken along the line A-A′ of FIG. 2;

FIG. 4 is an enlarged plan view illustrating a portion of a package substrate according to an example embodiment;

FIG. 5 is an enlarged plan view illustrating a portion of a package substrate according to an example embodiment;

FIG. 6 is an enlarged plan view illustrating a portion of a package substrate according to an example embodiment;

FIG. 7 is an enlarged plan view illustrating a portion of a package substrate according to an example embodiment;

FIG. 8 is an enlarged plan view illustrating a portion of a package substrate according to an example embodiment;

FIG. 9 is a plan view schematically illustrating a semiconductor package according to an example embodiment;

FIG. 10 is a plan view schematically illustrating a semiconductor package according to an example embodiment;

FIG. 11 is a cross-sectional view of the semiconductor package, taken along line BB′ of FIG. 9;

FIG. 12 is an enlarged view illustrating portion EX of FIG. 11; and

FIG. 13 is a cross-sectional view taken along line BB′ of FIG. 9 to illustrate a semiconductor package according to an example embodiment.

### DETAILED DESCRIPTION

The inventive concepts may be embodied in various different forms and various example embodiments, and specific example embodiments are described with reference to the accompanying drawings. However, the inventive concepts are not limited to the specific embodiments.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

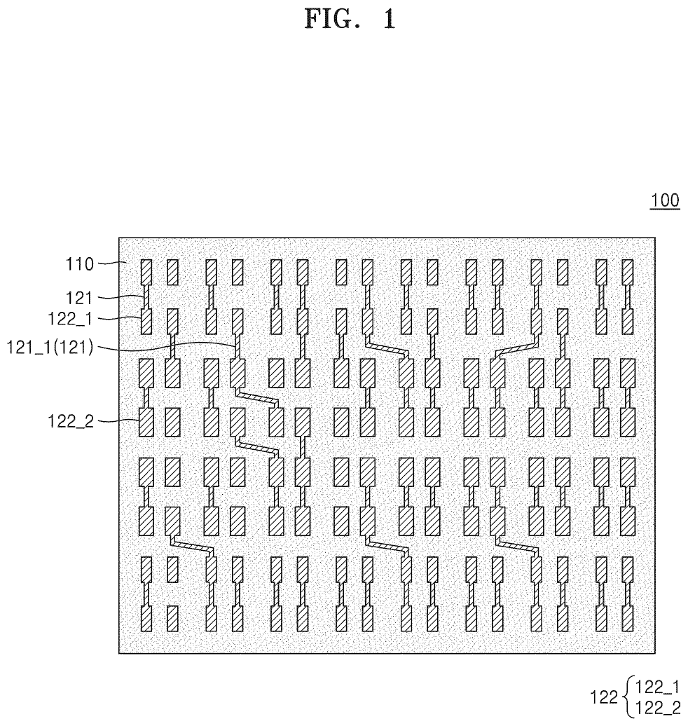

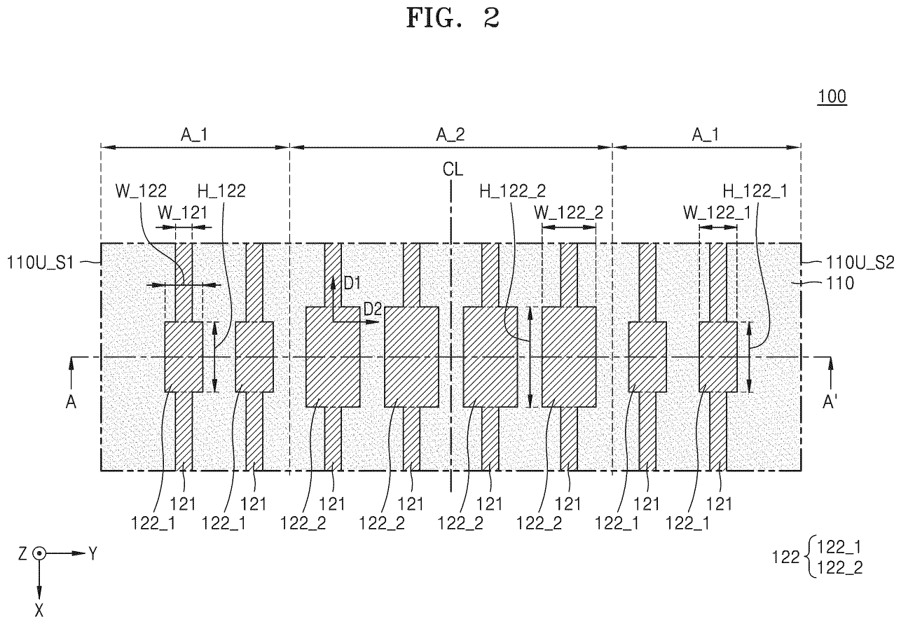

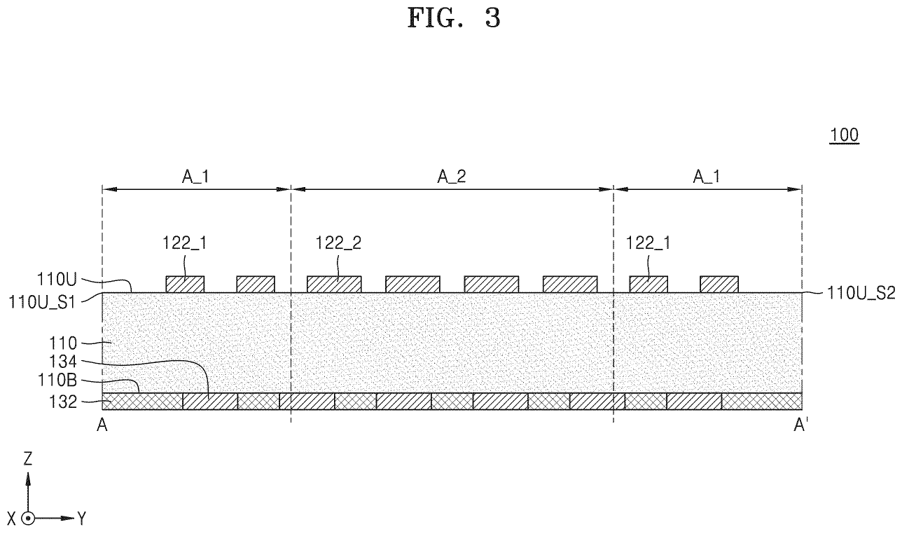

FIG. 1 is a schematic layout illustrating a package substrate 100 according to an example embodiment. FIG. 2 is an enlarged plan view illustrating a portion of the package substrate 100 shown in FIG. 1. FIG. 3 is a cross-sectional view of the package substrate 100, taken along line A-A′ of FIG. 2.

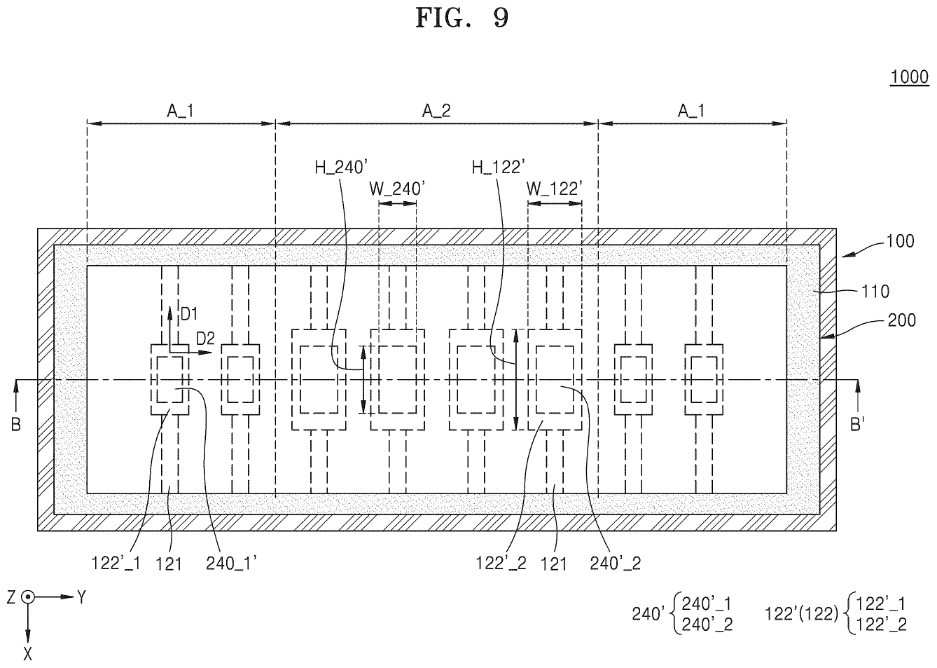

Referring to FIGS. 1 to 3, the package substrate 100 may include a substrate base 110, a plurality of wiring pads 122, and a plurality of wiring lines 121. The package substrate 100 may be a substrate for connecting a plurality of semiconductor chips 200 (refer to FIG. 9) to an external device. In an example embodiment, the package substrate 100 may be a printed circuit board (PCB). However, the package substrate 100 is not limited to the structure and material of the PCB and may be various types of substrates such as ceramic substrates.

In the following description, unless specifically defined, a direction parallel to a first surface 110U of the substrate base 110 is defined as a first horizontal direction (X direction), a direction perpendicular to the first surface 110U of the substrate base 110 is defined as a vertical direction (Z direction), and a direction perpendicular to the first horizontal direction (X direction) and the vertical direction (Z direction) is defined as a second horizontal direction (Y direction).

The substrate base 110 of the package substrate 100 may include the first surface 110U and a second surface 110B that is opposite to the first surface 110U. The wiring pads 122 may be arranged on the first surface 110U of the substrate base 110, and external contact pads 132 may be arranged on the second surface 110B of the substrate base 110. The substrate base 110 may include internal wiring (not shown) that electrically connects the wiring pads 122 and the external contact pads 132 to each other. In some example embodiments, the external contact pads 132 may be surrounded by a lower solder resist layer 134, and the wiring pads 122 may be exposed to the outside.

In some example embodiments, the substrate base 110 may include at least one material selected from the group consisting of a phenol resin, an epoxy resin, and polyimide. For example, the substrate base 110 may include at least one selected from the group consisting of polyimide, Flame Retardant 4 (FR-4), tetrafunctional epoxy, polyphenylene ether, epoxy/polyphenylene oxide, bismaleimide triazine (BT), Thermount, cyanate ester, and a liquid crystal polymer.

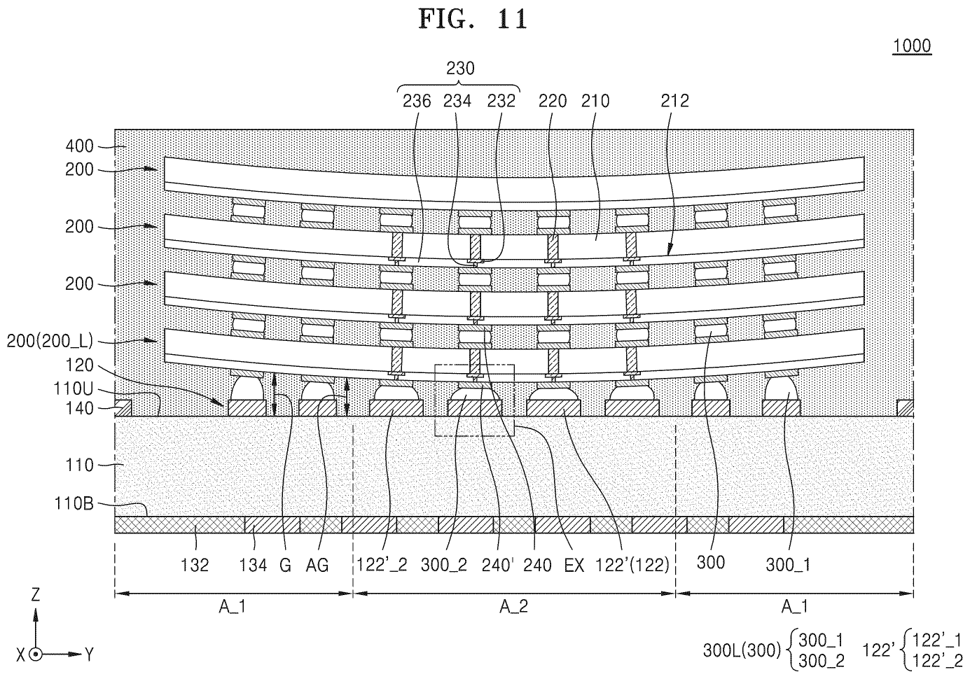

The wiring pads 122 of the package substrate 100 may be arranged on the first surface 110U of the substrate base 110. The wiring pads 122 may be regions that are in contact with a plurality of chip connection terminals 300 (described later with reference to FIG. 11). The wiring pads 122 may be apart from each other in horizontal directions, that is, the first horizontal direction (X direction) and the second horizontal direction (Y direction). Although FIG. 1 illustrates that the wiring pads 122 are arranged in a square shape, example embodiments are not limited thereto.

The wiring lines 121 of the package substrate 100 may be arranged on the first surface 110U of the substrate base 110. The wiring lines 121 may respectively extend from the wiring pads 122. In some example embodiments, each of the wiring lines 121 may electrically connect two wiring pads 122 to each other among the wiring pads 122.

In some example embodiments, first and second wiring pads 122_1 and 122_2 having different horizontal areas may be electrically connected to each other through wiring lines 121. First and second wiring pads 122_1 and 122_2 arranged in different regions may be electrically connected to each other through wiring lines 121. For example, first wiring pads 122_1 arranged in first regions A_1 and second wiring pads 122_2 arranged in a second region A_2 may be electrically connected to each other through first wiring lines 121_1.

Hereinafter, a direction in which each of the wiring lines 121 extends is defined as a first direction D1, and a direction perpendicular to the first direction D1 is defined as a second direction D2. Although FIG. 2 illustrates, for ease of illustration, that the first direction D1 is parallel to the first horizontal direction (X direction), example embodiments are not limited thereto, and the first direction D1 may not be parallel to the first horizontal direction (X direction).

In some example embodiments, the widths W_122 of the wiring pads 122 in the second direction D2 may be greater than the widths W_121 of the wiring lines 121 in the second direction D2. For example, in the vicinity of regions in which the wiring pads 122 are in contact with the wiring lines 121, the wiring pads 122 may protrude in the second direction D2 more than the wiring lines 121 because of a difference between the widths W_122 of the wiring pads 122 in the second direction D2 and the widths W_121 of the wiring lines 121 in the second direction D2.

The wiring pads 122 and the wiring lines 121 may be formed together. Although the wiring pads 122 and the wiring lines 121 are distinguished from each other by dashed lines in FIG. 2, the wiring pads 122 and the wiring lines 121 may actually be formed as one body. Furthermore, in some example embodiments, the wiring pads 122 and the wiring lines 121 may not be distinguished from each other as distinct elements and may be treated as one-body element.

In some example embodiments, the wiring pads 122 and the wiring lines 121 may include copper (Cu), tungsten (W), aluminum (Al), nickel (Ni), cobalt (Co), titanium (Ti), Titanium nitride (TiN), beryllium copper, or the like.

FIG. 2 is an enlarged view illustrating some of the wiring pads 122 of the package substrate 100 shown in FIG. 1. The arrangement of the wiring pads 122 is simply shown in FIG. 2 for ease of illustration, and example embodiments are not limited thereto.

In some example embodiments, each of the wiring pads 122 may have a shape in which the width H_122 of the wiring pad 122 in the first direction D1 is greater than the width W_122 of the wiring pad 122 in the second direction D2. For example, when the wiring pads 122 have a tetragonal shape, each of the wiring pads 122 may have a rectangular shape in which the length of a side parallel to the first direction D1 is greater than the length of a side parallel to the second direction D2.

The wiring pads 122 may have different sizes. For example, the wiring pads 122 arranged in different regions on the first surface 110U of the substrate base 110 may have different horizontal areas. In the present specification, the term “horizontal area” refers to the area of a surface parallel to the first surface 110U of the substrate base 110.

In some example embodiments, the first surface 110U of the substrate base 110 may include the first regions A_1 and the second region A_2. In some example embodiments, the second region A_2 may include the center of the substrate base 110, and the first regions A_1 may surround the second region A_2. For example, the first regions A_1 may include two opposite sides 110U_S1 and 110U_S2 of the first surface 110U of the substrate base 110, and the second region A_2 may include a center line CL passing through the center of the second surface 110B of the substrate base 110 and parallel to the sides 110U_S1 and 110U_S2. That is, the first regions A_1 may be arranged on both sides of the second region A_2.

The horizontal areas of the first wiring pads 122_1 arranged in the first regions A_1 may be different from the horizontal areas of the second wiring pads 122_2 arranged in the second region A_2. The horizontal areas of the first wiring pads 122_1 may be less than the horizontal areas of the second wiring pads 122_2. In some example embodiments, the horizontal areas of the first wiring pads 122_1 may be about 70% to about 90% of the horizontal areas of the second wiring pads 122_2.

For example, the widths H_122_1 of the first wiring pads 122_1 in the first direction D1 may be less than the widths H_122_2 of the second wiring pads 122_2 in the first direction D1, and/or the widths W_122_1 of the first wiring pads 122_1 in the second direction D2 may be less than the widths W_122_2 of the second wiring pads 122_2 in the second direction D2.

In some example embodiments, the widths H_122_1 of the first wiring pads 122_1 in the first direction D1 may range from about 80 μm to about 100 μm, and the widths H_122_2 of the second wiring pads 122_2 in the first direction D1 may range from about 100 μm to about 150 μm. The widths W_122_1 of the first wiring pads 122_1 in the second direction D2 may range from about 20 μm to about 50 μm, and the widths W_122_2 of the second wiring pads 122_2 in the second direction D2 may range from about 20 μm to about 100 μm.

Referring to FIG. 3, the package substrate 100 may include the external contact pads 132 and the lower solder resist layer 134 that are arranged on the second surface 110B of the substrate base 110. The external contact pads 132 may be surrounded by the lower solder resist layer 134. For example, the lower solder resist layer 134 may include a plurality of openings, and the external contact pads 132 may be formed in the openings. That is, the lower solder resist layer 134 may be positioned between the external contact pads 132. In some example embodiments, external contact terminals (not shown) may be attached to the external contact pads 132. The external contact terminals may include solder balls or solder bumps.

The wiring pads 122 may have different horizontal areas in regions of the package substrate 100, and thus, when semiconductor chips 200 (refer to FIG. 11) are mounted on the package substrate 100, electrical connection between the semiconductor chips 200 and the package substrate 100 may be reliably made. For example, the formation of a short circuit and an open circuit through the chip connection terminals 300 (refer to FIG. 11) between the semiconductor chips 200 and the package substrate 100 may be suppressed.

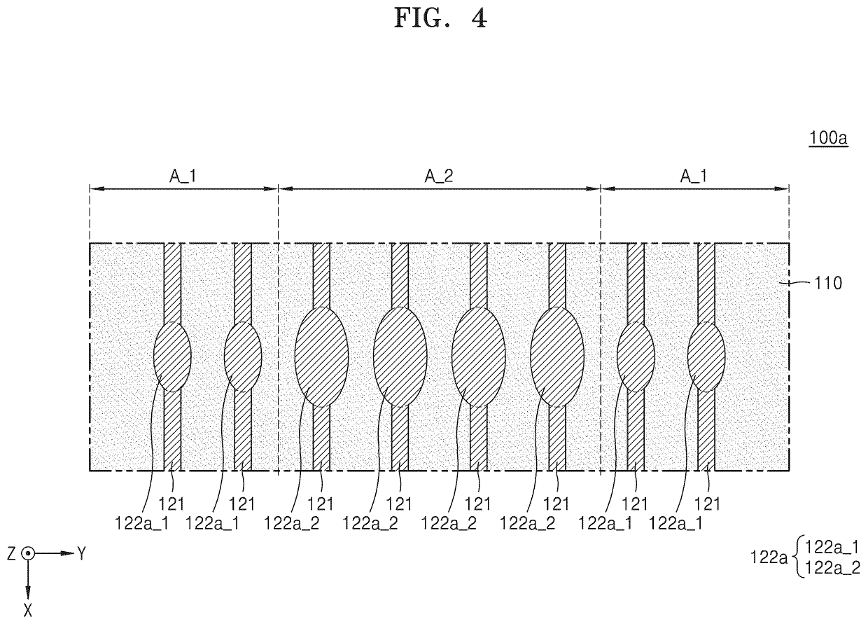

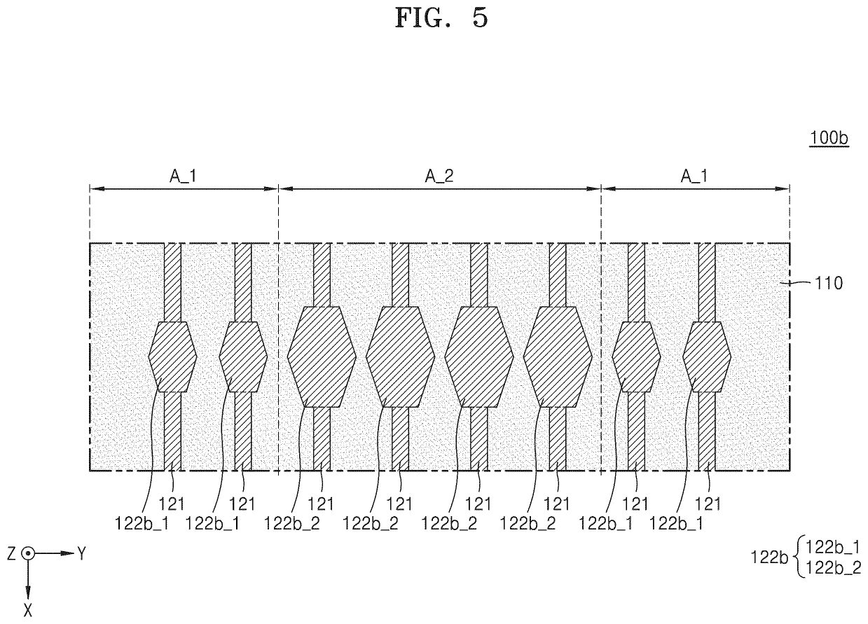

FIG. 4 is an enlarged plan view illustrating a portion of a package substrate 100a according to an example embodiment. FIG. 5 is an enlarged plan view illustrating a portion of a package substrate 100b according to an example embodiment.

Referring to FIGS. 4 and 5, the package substrates 100a and 100b may include substrate bases 110, a plurality of wiring pads 122a and 122b, and a plurality of wiring lines 121.

Descriptions of the same elements of the package substrates 100a and 100b shown in FIGS. 4 and 5 as the elements of the package substrate 100 shown in FIG. 2 will be omitted, and differences will now be described. The package substrates 100a and 100b shown in FIGS. 4 and 5 are different from the package substrate 100 shown in FIG. 2 in the shapes of the wiring pads 122a and 122b.

Referring to FIG. 4 together with FIG. 2, each of the wiring pads 122a of the package substrate 100a may have an elliptical shape. In some example embodiments, each of the wiring pads 122a may have an elliptical shape with a width in the first direction D1 being greater than a width in the second direction D2. That is, major axes of the wiring pads 122a may be parallel to the first direction D1 and minor axes of the wiring pads 122a may be parallel to the second direction D2.

For example, the wiring pads 122a may have different horizontal areas depending on regions in which the wiring pads 122a are arranged on the substrate base 110. The horizontal areas of first wiring pads 122a_1 arranged in first regions A_1 of the substrate base 110 may be less than the horizontal areas of second wiring pad 122a_2 arranged in a second region A_2 of the substrate base 110.

In some example embodiments, the lengths of the major axes of the first wiring pads 122a_1 may be less than the lengths of the major axes of the second wiring pads 122a_2 and the lengths of the minor axes of the first wiring pads 122a_1 may be less than the lengths of the minor axes of the second wiring pads 122a_2.

In some example embodiments, the lengths of the major axes of the first wiring pads 122a_1 may be less than the lengths of the major axes of the second wiring pads 122a_2 and the lengths of the minor axes of the first wiring pads 122a_1 may be equal to the minor axes of the second wiring pads 122a_2. That is, the horizontal areas of the wiring pads 122a may be adjusted by adjusting the lengths of the major axes of the wiring pads 122a.

Referring to FIG. 5 together with FIG. 2, each of the wiring pads 122b of the package substrate 100b may have a polygonal shape. For example, each of the wiring pads 122b may have a pentagonal or higher polygonal shape. In each of the wiring pads 122b, the greatest width in the first direction D1 may be greater than the greatest width in the second direction D2. That is, the greatest width of each of the wiring pads 122b in the first direction D1 may be greater than the greatest width of each of the wiring pads 122b in the second direction D2.

For example, the wiring pads 122b may have different horizontal areas depending on regions in which the wiring pads 122b are arranged on the substrate base 110. The horizontal areas of first wiring pads 122b_1 arranged in first regions A_1 of the substrate base 110 may be less than the horizontal areas of second wiring pads 122b_2 arranged in a second region A_2 of the substrate base 110.

However, the shape of each of the wiring pads 122b is not limited to those shown in FIGS. 2, 4, and 5 and may be variously modified.

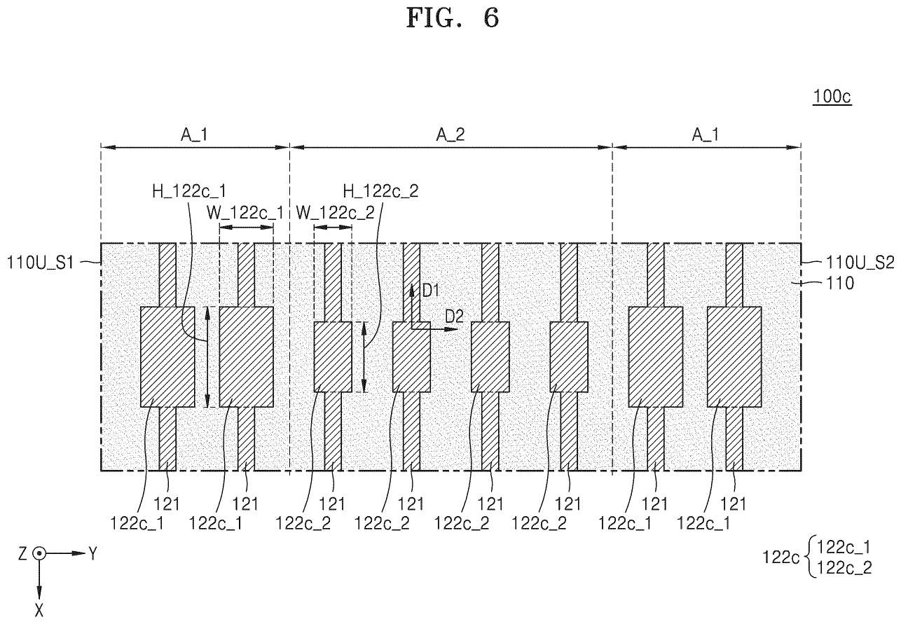

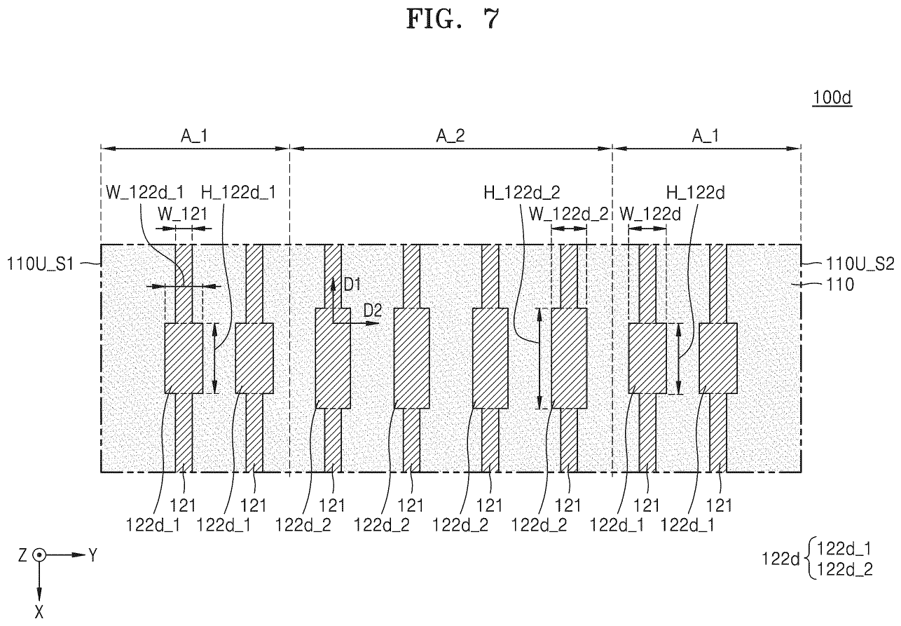

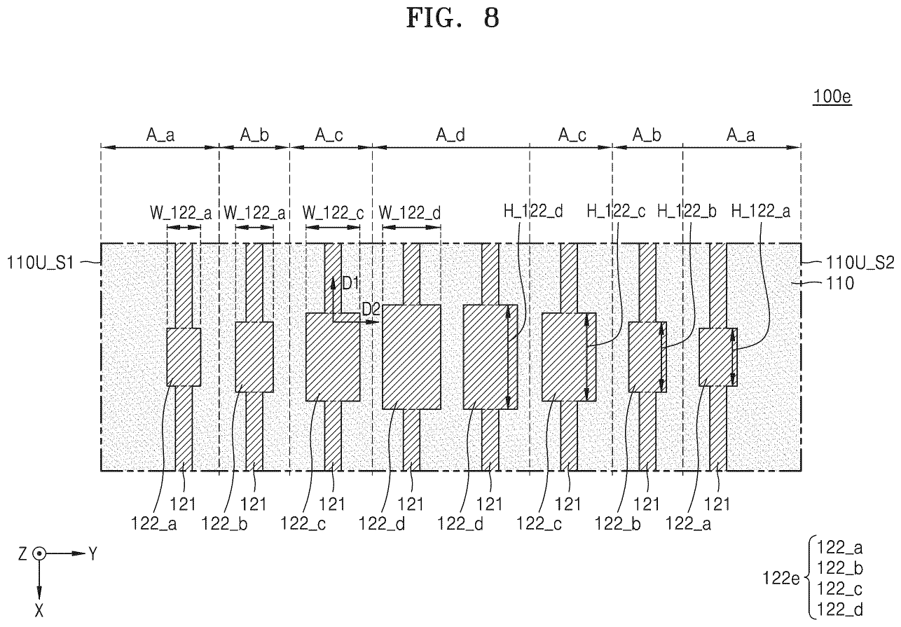

FIG. 6 is an enlarged plan view illustrating a portion of a package substrate 100c according to an example embodiment. FIG. 7 is an enlarged plan view illustrating a portion of a package substrate 100d according to an example embodiment. FIG. 8 is an enlarged plan view illustrating a portion of a package substrate 100e according to an example embodiment.

Referring to FIGS. 6 to 8, the package substrates 100c, 100d, and 100e may include substrate bases 110, a plurality of wiring pads 122c, 122d, and 122e, and a plurality of wiring lines 121.

Descriptions of the same elements of the package substrates 100c, 100d, and 100e shown in FIGS. 6 to 8 as the elements of the package substrate 100 shown in FIG. 2 will be omitted, and differences will now be described. The package substrates 100c, 100d, and 100e shown in FIGS. 6 to 8 are different from the package substrate 100 shown in FIG. 2 in the sizes of the wiring pads 122c, 122d, and 122e.

Referring to FIG. 6, the wiring pads 122c of the package substrate 100c may have different horizontal areas depending on regions in which the wiring pads 122c are arranged on the substrate base 110. First wiring pads 122c_1 may be arranged in first regions A_1 of the substrate base 110, that is, edge regions of the substrate base 110, and second wiring pads 122c_2 may be arranged in a second region A_2 of the substrate base 110, that is, a center region of the substrate base 110. In this case, the first wiring pads 122c_1 may be bigger than the second wiring pads 122c_2.

The horizontal areas of the first wiring pads 122c_1 and the second wiring pads 122c_2 may vary depending on the bending direction of semiconductor chips 200 (refer to FIG. 11) stacked on the package substrate 100c. For example, the horizontal areas of the wiring pads 122c may increase as the distance between the substrate base 110 and the semiconductor chips 200 decreases. For example, when the distance between the substrate base 110 and the semiconductor chips 200 is relatively small in the second region A_2 of the base substrate base 110, the horizontal areas of the second wiring pads 122c_2 may be larger than the horizontal areas of the first wiring pads 122c_1. This is described later with reference to FIG. 11.

Referring to FIG. 7, the wiring pads 122d of the package substrate 100d may have different horizontal areas depending on regions in which the wiring pads 122d are arranged on the substrate base 110. The wiring pads 122d having different horizontal areas may have the same width W_122d in the second direction D2 and different widths H_122d in the first direction D1. That is, the horizontal areas of the wiring pads 122d may be adjusted by adjusting the width H_122d of each of the wiring pads 122d in the first direction D1.

In some example embodiments, when the horizontal areas of first wiring pads 122d_1 arranged in first regions A_1 are less than the horizontal areas of second wiring pads 122d_2 arranged in a second region A_2 as shown in FIG. 2, the widths H_122d_1 of the first wiring pads 122d_1 in the first direction D1 may be less than the widths H_122d_2 of the second wiring pads 122d_2 in the first direction D1, and the widths W_122d_1 of the first wiring pads 122d_1 in the second direction D2 may be equal to the widths W_122d_2 of the second wiring pads 122d_2 in the second direction D2.

In some example embodiments, when the horizontal areas of the first wiring pad 122d_1 arranged in the first regions A_1 are greater than the horizontal areas of the second wiring pads 122d_2 arranged in the second region A_2 as shown in FIG. 6, the widths H_122d_1 of the first wiring pads 122d_1 in the first direction D1 may be greater than the widths H_122d_2 of the second wiring pads 122d_2 in the first direction D1, and the widths W_122d_1 of the first wiring pads 122d_1 in the second direction D2 may be equal to the widths W_122d_2 of the second wiring pads 122d_2 in the second direction D2.

Referring to FIG. 8, the wiring pads 122e of the package substrate 100e may have different horizontal areas depending on regions in which the wiring pads 122e are arranged on the substrate base 110. The horizontal areas of the wiring pads 122e may increase as the distance between the center of the substrate base 110 and the wiring pads 122e decreases. There may be three or more types of wiring pads 122e having different horizontal areas.

In some example embodiments, the substrate base 110 may have first to fourth regions A_a, A_b, A_c, and A_d. The distances from the center of the substrate base 110 to the first to fourth regions A_a, A_b, A_c, and A_d may decrease in the order from the first to fourth regions A_a, A_b, A_c, and A_d. That is, the fourth region A_d may include the center of the substrate base 110, the third regions A_c may surround the fourth region A_d, the second regions A_b may surround the third and fourth regions A_c and A_d, and the first regions A_a may surround the second to fourth regions A_b, A_c, and A_d. Therefore, the wiring pads 122e may be of four types having different horizontal areas.

As shown in FIG. 8, the horizontal areas of first wiring pads 122_a arranged in the first regions A_a may be less than the horizontal areas of second wiring pads 122_b arranged in the second regions A_b, the horizontal areas of the second wiring pads 122_b arranged in the second regions A_b may be less than the horizontal areas of third wiring pads 122_c arranged in the third regions A_c, and the horizontal areas of the third wiring pads 122_c arranged in the third regions A_c may be less than the horizontal areas of fourth wiring pads 122_d arranged in the fourth region A_d.

In some example embodiments, the widths H_122_a of the first wiring pads 122_a in the first direction D1 may be less than the widths H_122_b of the second wiring pads 122_b in the first direction D1, the widths H_122_b of the second wiring pads 122_b in the first direction D1 may be less than the widths H_122_c of the third wiring pads 122_c in the first direction D1, and the widths H_122_c of the third wiring pads 122_c in the first direction D1 may be less than the widths H_122_d of the fourth wiring pads 122_d in the first direction D1.

In some example embodiments, the widths W_122_a of the first wiring pads 122_a in the second direction D2 may be less than the widths W_122_b of the second wiring pads 122_b in the second direction D2, the widths W_122_b of the second wiring pads 122_b in the second direction D2 may be less than the widths W_122_c of the third wiring pads 122_c in the second direction D2, and the widths W_122_c of the third wiring pads 122_c in the second direction D2 may be less than the widths W_122_d of the fourth wiring pads 122_d in the second direction D2.

In some example embodiments, the wiring pads 122e may have the same width in the second direction D2 and different widths in the first direction D1.

Although FIG. 8 illustrates that the horizontal areas of the wiring pads 122e increase as the distances from the center of the substrate base 110 to the wiring pads 122e decrease, example embodiments are not limited thereto. In another example, the horizontal areas of the wiring pads 122e decrease as the distances from the center of the substrate base 110 to the wiring pads 122e decrease.

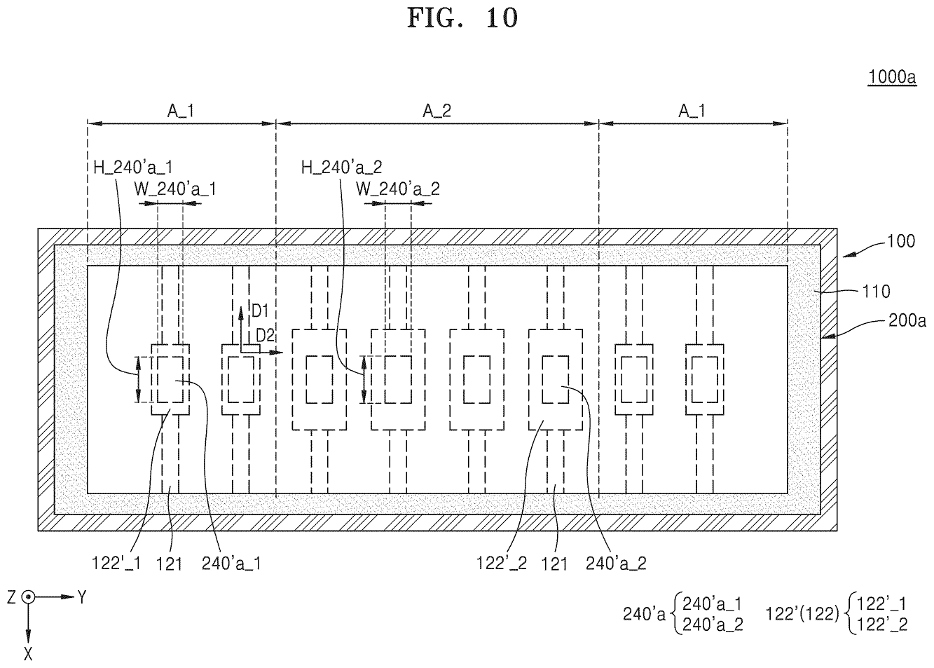

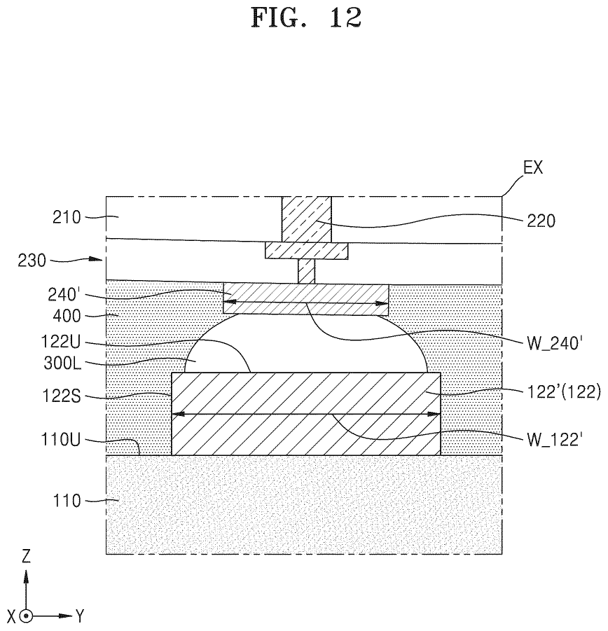

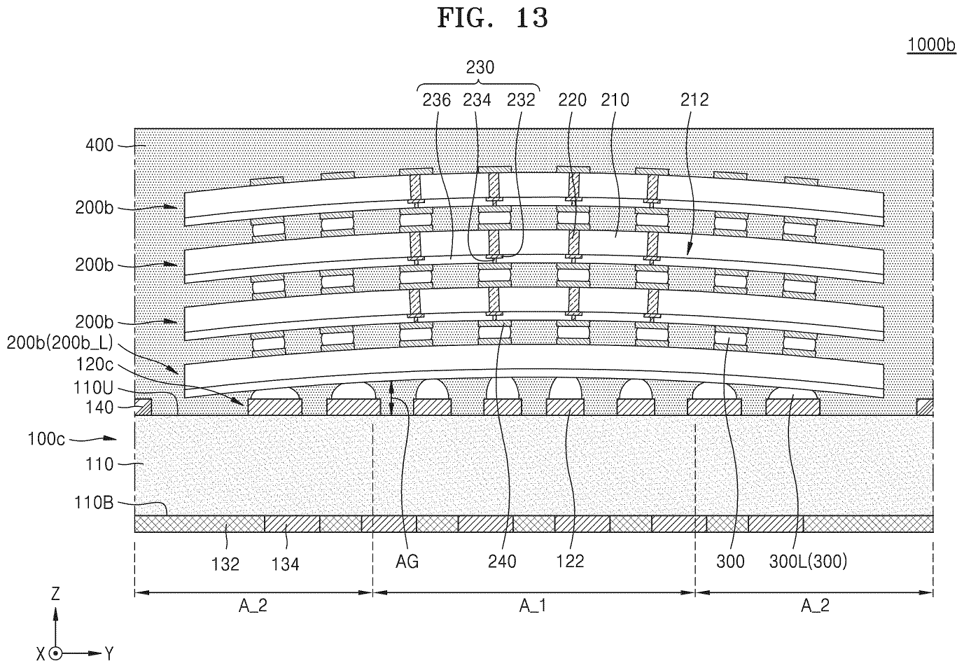

FIG. 9 is a plan view schematically illustrating a semiconductor package 1000 according to an example embodiment. FIG. 10 is a plan view schematically illustrating a semiconductor package 1000a according to an example embodiment. FIG. 11 is a cross-sectional view of the semiconductor package 1000, taken along line B-B′ of FIG. 9. FIG. 12 is an enlarged view illustrating portion EX of FIG. 11. FIG. 13 is a cross-sectional view taken along line B-B′ of FIG. 9 to illustrate a semiconductor package 1000b according to an example embodiment.

Referring to FIGS. 9 to 13, the semiconductor package 1000 may include a package substrate 100 and a plurality of semiconductor chips 200. FIGS. 9 and 10 are plan views transparently illustrating the semiconductor chips 200 to clearly illustrate a relationship between a plurality of lower-surface chip pads 240 (240′) and a plurality of wiring pads 122. Although FIGS. 9 to 12 exaggerate arrangements of the wiring pads 122 for ease of illustration, example embodiments are not limited thereto.

The package substrate 100 of the semiconductor package 1000 may include a substrate base 110, the wiring pads 122, and a plurality of wiring lines 121. The package substrate 100 shown in FIG. 9 may be any one of the package substrates described above (refer to reference numerals 100 in FIG. 2, 100a in FIG. 4, 100b in FIG. 5, 100c in FIG. 6, 100d in FIG. 7, and 100e in FIG. 8).

In some example embodiments, misalignment may occur between the wiring pads 122 of the package substrate 100 and the lower-surface chip pads 240 of the semiconductor chips 200 because of warpage of the semiconductor chips 200 during a mass-reflow (MR) process. As described above, the horizontal areas of the wiring pads 122 may be greater than the horizontal areas of the wiring lines 121, and thus, a phenomenon in which some of a plurality of chip connection terminals 300 are opened may be suppressed even when the semiconductor chips 200 and the package substrate 100 are misaligned with each other.

The semiconductor chips 200 of the semiconductor package 1000 may be disposed on a first surface 110U of the package substrate 100. The semiconductor chips 200 may each include a semiconductor substrate 210, penetration electrodes 220, a wiring structure 230, and a plurality of lower-surface chip pads 240.

The semiconductor chips 200 may be sequentially stacked on the package substrate 100 in a vertical direction with active surfaces of the semiconductor chips 200 facing downward, that is, facing the package substrate 100. A semiconductor chip 200 that is closest to the package substrate 100 among the semiconductor chips 200 is referred to as a lowermost semiconductor chip 200_L.

In some example embodiments, the semiconductor chips 200 may have bent shapes that are convex in the same direction. Warpage may occur on all of the semiconductor chips 200 in a certain direction. When the semiconductor chips 200 each have a convex shape such that the centers of the semiconductor chips 200 are relatively close to the package substrate 100, the semiconductor chips 200 may be referred to as “having a smile-type bent shape,” and when the semiconductor chips 200 each have a convex shape such that the centers of the semiconductor chips 200 are relatively far from the package substrate 100, the semiconductor chips 200 may be referred to as “having a crying-type bent shape.” The semiconductor chips 200 of the semiconductor package 1000 shown in FIG. 11 have a smile-type bent shape, and semiconductor chips 200b of the semiconductor package 1000b shown in FIG. 13 have a crying-type bent shape.

When the semiconductor chips 200 have bent shapes that are convex in the same direction, the distance G between the first surface 110U of the substrate base 110 of the package substrate 100 and the lowermost semiconductor chip 200_L may vary depending on regions of the substrate base 110.

In some example embodiments, wiring pads 122 arranged in a region in which the distance G between the lowermost semiconductor chip 200_L and the first surface 110U of the substrate base 110 is relatively large may have relatively small horizontal areas.

For example, during an MR process, the semiconductor chips 200 may undergo warpage, and in this case, deformation of the chip connection terminals 300 positioned between the lowermost semiconductor chip 200_L and the package substrate 100 may increase as variations in the heights of the semiconductor chips 200 increase. In the semiconductor package 1000, wiring pads 122 arranged in a region in which the distance G between the substrate base 110 and the lowermost semiconductor chip 200_L is relatively small may have relatively large horizontal areas to suppress a situation in which even the substrate base 110 is deformed due to the deformation of the chip connection terminals 300.

When the semiconductor chips 200 have a smile-type bent shape as shown in FIG. 11, the distance G between the lowermost semiconductor chip 200_L and the substrate base 110 may increase in directions toward edges of the substrate base 110. Therefore, the horizontal areas of wiring pads 122 disposed adjacent to the edges of the substrate base 110 may be smallest among the horizontal areas of the wiring pads 122.

For example, when the semiconductor chips 200b have a crying-type bent shape as shown in FIG. 13, the distance G between the lowermost semiconductor chip 200b_L and the substrate base 110 may increase in directions toward the center of the substrate base 110. Therefore, the horizontal areas of wiring pads 122 disposed adjacent to the edges of the substrate base 110 may be largest among the horizontal areas of the wiring pads 122.

In some example embodiments, the average of the distance G between the substrate base 110 and the lowermost semiconductor chip 200_L is referred to as an average distance AG. For example, the average distance AG may be calculated by integrating the distance G between the first surface 110U of the substrate base 110 and a lower surface of the lowermost semiconductor chip 200_L, and dividing the integrated distance G by the horizontal area of the lower surface of the lowermost semiconductor chip 200_L.

First regions A_1 of the substrate base 110 may be regions in which the distance G between the substrate base 110 and the lowermost semiconductor chip 200_L is greater than the average distance AG, and a second region A_2 of the substrate base 110 may be a region in which the distance G between the substrate base 110 and the lowermost semiconductor chip 200_L is less than the average distance AG. In some example embodiments, wiring pads 122 arranged in the first regions A_1 may have smaller horizontal areas than wiring pads 122 arranged in the second region A_2. Although FIGS. 9 to 13 illustrate that the substrate base 110 is divided into the first and second regions A_1 and A_2, example embodiments are not limited thereto. For example, the substrate base 110 may be divided into three or more regions.

In some example embodiments, when the semiconductor chips 200 have a smile-type bent shape as shown in FIG. 11, the first regions A_1 and the second region A_2 of the substrate base 110 may be substantially the same as the first regions A_1 and the second region A_2 that are shown in FIG. 2. For example, the arrangement of the wiring pads 122 of the package substrate 100 shown in FIG. 11 may be substantially the same as the arrangement of the wiring pads 122 of the package substrate 100 shown in FIG. 2.

In some example embodiments, when the semiconductor chips 200b have a crying-type bent shape as shown in FIG. 13, first regions A_1 and a second region A_2 of a substrate base 110 may be substantially the same as the first regions A_1 and the second region A_2 that are shown in FIG. 6. For example, the arrangement of wiring pads 122 of a package substrate 100c that is shown in FIG. 13 may be substantially the same as the arrangement of the wiring pads 122 of the package substrate 100c that is shown in FIG. 6.

The semiconductor substrate 210 may include, for example, a semiconductor material such as silicon (Si). In some example embodiments, the semiconductor substrate 210 may include a semiconductor material such as germanium (Ge). The semiconductor substrate 210 may have an active surface and an inactive surface that is opposite to the active surface. The semiconductor substrate 210 may include a conductive region, for example, a well region doped with a dopant. The semiconductor substrate 210 may have various device isolation structures such as a shallow trench isolation (STI) structure.

Each of semiconductor devices 212 may include various individual devices. The individual devices may include various microelectronic devices. Examples of the individual devices may include metal-oxide-semiconductor field effect transistors (MOSFETs) such as complementary metal-oxide-semiconductor (CMOS) transistors, system large scale integration (LSI) devices, image sensors such as CMOS imaging sensors (CSIs), micro-electro-mechanical systems (MEMS), active devices, passive devices, and the like.

The individual devices may be electrically connected to the conductive region of the semiconductor substrate 210. The semiconductor devices 212 may further include conductive lines or conductive plugs that electrically connect at least two of the individual devices or the individual devices to the conductive region of the semiconductor substrate 210. In addition, each of the individual devices may be electrically separated from other neighboring individual devices by an insulating film.

At least one of the semiconductor chips 200 may be a memory semiconductor chip. In some example embodiments, one of the semiconductor chips 200 may be a buffer chip including a serial-parallel conversion circuit and configured to control the other semiconductor chips 200, and the other semiconductor chips 200 may be memory chips each including memory cells.

For example, the semiconductor package 1000 including the semiconductor chips 200 may be a high bandwidth memory (HBM) package. In this case, one of the semiconductor chips 200 may be referred to as an HBM controller die, and the other semiconductor chips 200 may be referred to as dynamic random access memory (DRAM) dies.

The wiring structure 230 may include a plurality of wiring patterns 232, a plurality of wiring vias 234 connected to the wiring patterns 232, and an inter-wiring insulation layer 236 surrounding the wiring patterns 232 and the wiring vias 234. In some example embodiments, the wiring structure 230 may have a multi-layer wiring structure including the wiring patterns 232 and the wiring vias 234 at different vertical levels.

The wiring patterns 232 and the wiring vias 234 may include, for example, a metallic material such as aluminum (Al), copper (Cu), or tungsten (W). In some example embodiments, the wiring patterns 232 and the wiring vias 234 may include a wiring barrier film and a wiring metal layer. The wiring barrier film may include a metal, a metal nitride, or an alloy. The wiring metal layer may include at least one metal selected from the group consisting of tungsten (W), aluminum (Al), titanium (Ti), tantalum (Ta), ruthenium (Ru), manganese (Mn), and copper (Cu).

When the wiring structure 230 has a multi-layer wiring structure, the inter-wiring insulating layer 236 may have a multi-layer structure in which a plurality of insulating layers are stacked corresponding to the multi-layer wiring structure of the wiring structure 230. For example, the inter-wiring insulating layer 236 may include silicon oxide, silicon nitride, silicon oxynitride, an insulating material having a lower dielectric constant than silicon oxide, or a combination thereof. In some example embodiments, the inter-wiring insulation layer 236 may include a tetraethyl orthosilicate (TEOS) film, or an ultralow K (ULK) film having an ultralow dielectric constant K within a range of about 2.2 to about 2.4. The ULK film may include a SiOC film or a SiCOH film.

The penetration electrodes 220 may each include a through silicon via (TSV). The penetration electrodes 220 may each include a conductive plug penetrating the semiconductor substrate 210 and a conductive barrier film surrounding the conductive plug. A via insulating film may be arranged between the penetration electrodes 220 and the semiconductor substrate 210 and may surround side walls of the penetration electrodes 220.

The lower-surface chip pads 240 may be arranged on the wiring structure 230. Each of the lower-surface chip pads 240 may be apart from the semiconductor substrate 210 with the wiring structure 230 therebetween. The lower-surface chip pads 240 may be electrically connected to the wiring vias 234. Unless otherwise specified, the lower-surface chip pads 240 may refer to chip pads provided on lower surfaces of the semiconductor chips 200.

The chip connection terminals 300 may be provided on the lower-surface chip pads 240, and the lower-surface chip pads 240 of each of the semiconductor chips 200 may be electrically connected to the wiring pads 122 of the package substrate 100. Hereinafter, among the wiring pads 122 and the lower-surface chip pads 240, wiring pads 122 and lower-surface chip pads 240 that are physically connected to each other by the chip connection terminals 300 are respectively referred to as lower wiring pads 122′ and upper lower-surface chip pads 240′. In some example embodiments, the upper lower-surface chip pads 240′ may overlap the lower wiring pads 122′ in the vertical direction (Z direction).

In some example embodiments, the lower wiring pads 122′ may have larger horizontal areas than the upper lower-surface chip pad 240′. For example, each of the wiring pads 122 may be larger than the nearest of the lower-surface chip pads 240 of the lowermost semiconductor chip 200_L. That is, each of the wiring pads 122 may have a larger horizontal area than a lower-surface chip pad 240 that overlaps the wiring pad 122 in the vertical direction (Z direction) among the lower-surface chip pads 240 of the lowermost semiconductor chip 200_L.

In some example embodiments, the widths H_122′ of the lower wiring pads 122′ in the first direction D1 may be greater than the widths H_240′ of the upper lower-surface chip pads 240′ in the first direction D1. In some example embodiments, the widths H_122′ of the lower wiring pads 122′ in the first direction D1 may be about 150% to about 200% of the widths H_240′ of the upper lower-surface chip pads 240′ in the first direction D1.

In some example embodiments, the widths W_122′ of the lower wiring pads 122′ in the second direction D2 may be greater than the widths W_240′ of the upper lower-surface chip pads 240′ in the second direction D2. In some example embodiments, the widths W_122′ of the lower wiring pads 122′ in the second direction D2 may be about 100% to about 150% of the widths W_240′ of the upper lower-surface chip pads 240′ in the second direction D2.

When the horizontal areas of first lower wiring pads 122′_1 provided in the first regions A_1 are different from the horizontal areas of second lower wiring pads 122′_2 arranged in the second region A_2 as shown in FIG. 9, the horizontal areas of first upper lower-surface chip pads 240′_1 corresponding to the first lower wiring pads 122′_1 may be different from the horizontal areas of second upper lower-surface chip pads 240′_2 corresponding to the second lower wiring pads 122′_2. For example, the horizontal areas of the first upper lower-surface chip pads 240′_1 and the horizontal areas of the second upper lower-surface chip pads 240′_2 may vary respectively depending on the horizontal areas of the first lower wiring pads 122′_1 and the horizontal areas of the second lower wiring pads 122′_2.

However, as shown in FIG. 10, lowermost lower-surface chip pads 240′a of semiconductor chips 200a of the semiconductor package 1000a may have identical horizontal areas. For example, first upper lower-surface chip pads 240′a_1 provided straight above first regions A_1 of a substrate base 110, and second upper lower-surface chip pads 240′a_2 provided straight above a second region A_2 of the substrate base 110 may have the same horizontal area. That is, the horizontal areas of the first upper lower-surface chip pads 240′a_1 and the horizontal areas of the second upper lower-surface chip pad 240′a_2 may respectively be independent of the horizontal areas of first lower wiring pads 122′_1 and the horizontal areas of second lower wiring pads 122′_2.

For example, when the horizontal areas of the first lower wiring pads 122′_1 are less than the horizontal areas of the second lower wiring pads 122′_2, the horizontal areas of the first upper lower-surface chip pads 240′a_1 may be the same as the horizontal areas of the second upper lower-surface chip pads 240′a_2. That is, the widths H_240′a_1 of the first upper lower-surface chip pads 240′a_1 in the first direction D1 and the widths H_240 of the second upper lower-surface chip pads 240′a_2 in the first direction D1′a_2 may be identical to each other, and the widths W_240′a_1 of the first upper lower-surface chip pads 240′a_1 in the second direction D2 and the widths W_240′a_1 of the second upper lower-surface chip pads 240′a_2 in the second direction D2 may be identical to each other.

Referring back to FIGS. 9, 11, and 12, the chip connection terminals 300 of the semiconductor package 1000 may be arranged between the package substrate 100 and the lowermost semiconductor chip 200_L and between the semiconductor chips 200. In some example embodiments, the chip connection terminals 300 may include solder balls or solder bumps.

Among the chip connection terminals 300, chip connection terminals 300 arranged between the wiring pads 122 of the package substrate 100 and the lower-surface chip pads 240 of the lowermost semiconductor chip 200_L may be referred to as lowermost chip connection terminals 300L. The lowermost chip connection terminals 300L may be apart from the substrate base 110 with the wiring pads 122 of the package substrate 100 arranged therebetween. In other words, the lowermost chip connection terminals 300L may not be in contact with the first surface 110U of the substrate base 110.

In some example embodiments, the lowermost chip connection terminals 300L may include first chip connection terminals 300_1 and second chip connection terminals 300_2.

The first chip connection terminals 300_1 may be in the first regions A_1, and the second chip connection terminals 300_2 may be in the second region A_2. That is, the first chip connection terminals 300_1 may be arranged in a region in which the distance G between the package substrate 100 and the lowermost semiconductor chip 200_L is greater than the average distance AG, and the second chip connection terminals 300_2 may be arranged in a region in which the distance G between the package substrate 100 and the lowermost semiconductor chip 200_L is less than the average distance AG.

The first chip connection terminals 300_1 may have a smaller height (e.g., a width in a first horizontal direction (X direction)) than the second chip connection terminals 300_2, and a smaller horizontal width (e.g., a width in a second horizontal direction (Y direction)) than the second chip connection terminals 300_2 (for example, the first chip connection terminals 300_1 may have smaller widths than the second chip connection terminals 300_2 in the first horizontal direction (X direction) and the second horizontal direction (Y direction), respectively). For example, during an MR process and a molded underfill (MUF) process, lowermost chip connection terminals 300L arranged in a region in which the distance G between the package substrate 100 and the lowermost semiconductor chip 200_L is relatively small may receive a relatively large amount of external force in the vertical direction (Z direction) and may thus undergo a relatively large amount of deformation in the first horizontal direction (X direction) and the second horizontal direction (Y direction).

A molding layer 400 of the semiconductor package 1000 may cover the first surface 110U of the substrate base 110 and may surround the semiconductor chips 200 and the chip connection terminals 300. That is, the molding layer 400 may fill a space between the package substrate 100 and the lowermost semiconductor chip 200_L and a space between the semiconductor chips 200. In some example embodiments, the molding layer 400 may include an epoxy mold compound (EMC).

The molding layer 400 may be formed on the package substrate 100 through an MUF process without a separate underfill process. Therefore, the molding layer 400 may fill a space between the wiring pads 122 and a space between the chip connection terminals 300.

Referring to FIG. 12, the semiconductor package 1000 may include the lower wiring pads 122′ having larger horizontal areas than the upper lower-surface chip pads 240′. In some example embodiments, the widths W_122′ of the lower wiring pads 122′ in the second direction D2 may be greater than the widths W_240′ of the upper lower-surface chip pads 240′ in the second direction D2. Therefore, the lowermost chip connection terminals 300L may be mitigated or prevented from flowing to the first surface 110U of the substrate base 110. That is, each of the chip connection terminals 300 may not be in contact with side surfaces 122S of the wiring pads 122.

In some example embodiments, the lowermost chip connection terminals 300L may be in contact with at least portions of upper surfaces 122U of the lower wiring pads 122′, and the molding layer 400 may completely cover the side surfaces 122S of the lower wiring pads 122′ and may cover the other portions of the upper surfaces 122U of the lower wiring pads 122′.

In some example embodiments, the semiconductor package 1000 may further include an upper solder resist layer 140. The upper solder resist layer 140 may be provided on the first surface 110U of the substrate base 110. The upper solder resist layer 140 may partially cover a region of the first surface 110U of the substrate base 110 that does not overlap the semiconductor chips 200. That is, the upper solder resist layer 140 may not be provided in a space in which the wiring pads 122 are apart from each other and a space in which the wiring lines 121 are apart from each other. Therefore, during an MUF process, a molding material may be filled between the wiring lines 121 and the wiring pads 122, and thus, the molding layer 400 may completely be in contact with side surfaces of the wiring lines 121 and the side surfaces 122S of the wiring pads 122.

While the inventive concepts have been particularly shown and described with reference to some example embodiments thereof, it will be understood that various changes in form and details may be made therein without departing from the spirit and scope of the following claims.

What is claimed is:

1. A package substrate comprising:
a substrate base comprising a first surface and a second surface that is opposite to the first surface, the substrate base being divided into a plurality of regions;
a plurality of wiring pads arranged on the first surface of the substrate base and apart from each other in a horizontal direction; and
a plurality of wiring lines arranged on the first surface of the substrate base and extending from corresponding ones of the plurality of wiring pads, respectively,
wherein the plurality of wiring pads have different horizontal areas in different regions of the substrate base.

2. The package substrate of claim 1, wherein
the plurality of regions of the substrate base comprises first regions comprising two opposite sides of the first surface of the substrate base and a second region surrounded by the first regions, and
from among the plurality of wiring pads, horizontal areas of first wiring pads arranged in the first regions are different from horizontal areas of second wiring pads arranged in the second region.

3. The package substrate of claim 1, wherein, when a direction in which the plurality of wiring lines extend from the plurality of wiring pads, respectively, is a first direction and a direction perpendicular to the first direction is a second direction, a width of each of the plurality of wiring pads in the first direction is greater than a width of each of the plurality of wiring pads in the second direction.

4. The package substrate of claim 3, wherein
the plurality of wiring pads comprise first and second wiring pads arranged in different regions,
widths of the first wiring pads in the first direction are different from widths of the second wiring pads in the first direction, and
widths of the first wiring pads in the second direction are equal to widths of the second wiring pads in the second direction.

5. The package substrate of claim 1, wherein
the plurality of wiring pads comprise first and second wiring pads arranged in different regions, and
the plurality of wiring lines comprise first wiring lines extending from the first wiring pads to corresponding ones of the second wiring pads, respectively.

6. The package substrate of claim 1, wherein, when a direction in which the plurality of wiring lines extend from the plurality of wiring pads, respectively, is a first direction and a direction perpendicular to the first direction is a second direction, widths of the plurality of wiring pads in the second direction are greater than widths of the plurality of wiring lines in the second direction.

7. A semiconductor package comprising:
a substrate base comprising a first surface and a second surface that is opposite to the first surface, the substrate base being divided into a plurality of regions;
a plurality of wiring pads arranged on the first surface of the substrate base and apart from each other in a horizontal direction;
a plurality of wiring lines extending from corresponding ones of the plurality of wiring pads, respectively;
a plurality of semiconductor chips stacked on the first surface of the substrate base and each comprising a plurality of lower-surface chip pads; and
a plurality of chip connection terminals arranged between the substrate base and a lowermost semiconductor chip among the plurality of semiconductor chips and between the plurality of semiconductor chips,
wherein the plurality of wiring pads have different horizontal areas in different regions of the substrate base.

8. The semiconductor package of claim 7, wherein the plurality of semiconductor chips have bent shapes that are convex in an identical direction.

9. The semiconductor package of claim 8, wherein among the plurality of wiring pads, a first wiring pad arranged in a first region in which a distance between the lowermost semiconductor chip and the first surface of the substrate base has a first value has a horizontal area smaller than second wiring pad arranged in a second region in which the distance between the lowermost semiconductor chip and the first surface of the substrate base has a second value, the second value being smaller than the first value.

10. The semiconductor package of claim 8, wherein
the plurality of regions of the substrate base comprise a first region and a second region,
the first region of the substrate base is a region in which a vertical distance between the lowermost semiconductor chip and the first surface of the substrate base is greater than an average distance between the lowermost semiconductor chip and the first surface of the substrate base in a vertical direction,
the second region of the substrate base is a region in which the vertical distance between the lowermost semiconductor chip and the first surface of the substrate base is less than the average distance, and
from among the plurality of wiring pads, horizontal areas of first wiring pads arranged in the first region are less than horizontal areas of second wiring pads arranged in the second region.

11. The semiconductor package of claim 10, wherein from among the plurality of lower-surface chip pads, horizontal areas of first lower-surface chip pads being straightly above the first region of the substrate base are equal to horizontal areas of second lower-surface chip pads being straightly above the second region of the substrate base.

12. The semiconductor package of claim 8, wherein
the plurality of wiring pads comprise lower wiring pads,
the plurality of lower-surface chip pads of the lowermost semiconductor chip comprise upper lower-surface chip pads overlapping the lower wiring pads in a vertical direction, and
horizontal areas of the lower wiring pads are greater than horizontal areas of the upper lower-surface chip pads.

13. The semiconductor package of claim 12, wherein, when a direction in which the wiring lines extend from the corresponding ones of the plurality of wiring pads is a first direction and a direction perpendicular to the first direction is a second direction,
widths of the lower wiring pads in the first direction are greater than widths of the upper lower-surface chip pads in the first direction, and
widths of the lower wiring pads in the second direction are greater than or equal to widths of the upper lower-surface chip pads in the second direction.

14. The semiconductor package of claim 13, wherein
the widths of the lower wiring pads in the first direction are about 150% to about 200% of the widths of the upper lower-surface chip pads in the first direction, and
the widths of the lower wiring pads in the second direction are about 100% to about 150% of the widths of the upper lower-surface chip pads in the second direction.

15. The semiconductor package of claim 8, further comprising:
an upper solder resist layer on the first surface of the substrate base,
wherein the upper solder resist layer does not overlap the plurality of semiconductor chips in a vertical direction.

16. The semiconductor package of claim 8, wherein the plurality of chip connection terminals are not in contact with side surfaces of the plurality of wiring pads.

17. A semiconductor package comprising:
a substrate base comprising a first surface and a second surface that is opposite to the first surface, the substrate base being divided into a plurality of regions;
a plurality of wiring pads arranged on the first surface of the substrate base and apart from each other in a horizontal direction;
a plurality of wiring lines extending from corresponding ones of the plurality of wiring pads, respectively;
a plurality of semiconductor chips stacked on the first surface of the substrate base and each comprising a plurality of lower-surface chip pads;
external contact pads arranged on the second surface of the substrate base;
an upper solder resist layer positioned in a region of the first surface of the substrate base that does not overlap the plurality of semiconductor chips;
a lower solder resist layer covering the second surface of the substrate base and surrounding the external contact pads;
a plurality of chip connection terminals arranged between the substrate base and a lowermost semiconductor chip among the plurality of semiconductor chips and between the plurality of semiconductor chips; and
a molding layer covering the first surface of the substrate base and surrounding the plurality of semiconductor chips and the plurality of chip connection terminals,
wherein the lowermost semiconductor chip comprises upper lower-surface chip pads overlapping lower wiring pads of the plurality of wiring pads, respectively, in a vertical direction,
horizontal areas of the upper lower-surface chip pads are less than horizontal areas of the lower wiring pads,
the plurality of wiring pads arranged in different regions of the substrate base have different horizontal areas, and
the plurality of semiconductor chips have bent shapes that are convex in an identical direction.

18. The semiconductor package of claim 17, wherein
the molding layer fills a space between the plurality of wiring pads and a space between the plurality of chip connection terminals, and
side surfaces of the plurality of wiring pads are completely covered by the molding layer.

19. The semiconductor package of claim 17, wherein among the plurality of wiring pads, a first wiring pad arranged in a first region in which a distance between the lowermost semiconductor chip and the first surface of the substrate base has a first value have a horizontal areas area smaller than a second wiring pad arranged in a second region in which the distance between the lowermost semiconductor chip and the first surface of the substrate base has a second value, the second value being smaller than the first value.

20. The semiconductor package of claim 17, wherein
when a direction in which the wiring lines extend from the corresponding ones of the plurality of wiring pads, respectively, is a first direction and a direction perpendicular to the first direction is a second direction,
widths of the lower wiring pads in the first direction are greater than widths of the upper lower-surface chip pads in the first direction, and
widths of the lower wiring pads in the second direction are greater than or equal to widths of the upper lower-surface chip pads in the second direction.
